(19) United States
(12) Patent Application Publication
(10) Pub. No.: US 2003/0049893 A1
(43) Pub. Date: Mar. 13, 2003

(54) Method for isolating semiconductor devices

(76) Inventors: Matthew Currie, Boston, MA (US); Richard Hammond, Cambridge, MA (US)

Correspondence Address: TESTA, HURWITZ & THIBEAULT, LLP, HIGH STREET TOWER, 125 HIGH STREET, BOSTON, MA, 02110, US

(21) Appl. No.: 10/165,031

(22) Filed: Jun. 7, 2002

Related U.S. Application Data
(60) Provisional application No. 60/296,976, filed on Jun. 8, 2001.

(51) Int. Cl. H01L 21/338; H01L 21/336; H01L 21/76

(52) U.S. Cl. 438/172; 438/424; 438/296

(57) ABSTRACT

A method is disclosed for isolating device regions in a heterostructure that includes at least one layer of a strained semiconductor material. The method includes the steps of forming a trench in the at least one layer of strained semiconductor material using an etch chemistry that is selected to etch different layers of said heterostructure sufficiently similarly that said trench includes walls that are substantially straight, and depositing a dielectric material in the trench.

The present application claims priority to U.S. Provisional Patent Application Ser. No. 60/296,976 filed Jun. 8, 2001.

### BACKGROUND OF THE INVENTION

The invention relates generally to the processing of strained silicon and/or germanium substrates and relates in particular to the processing of silicon heterostructures including relaxed SiGe alloys for the purpose of forming transistors therefrom.

Substrates formed of relaxed SiGe alloys permit the production of a host of strained Si, Ge, and SiGe-based transistors. Utilizing both strain and bandgap engineering, these MODFETs and MOSFETs may be tailored toward enhanced-performance analog and/or digital applications. Such devices, however, present many processing challenges since these devices are fabricated on SiGe virtual substrates rather than the Si substrates commonly utilized for VLSI CMOS technologies.

One of the most important modules of device processing that must be optimized for fabrication on SiGe virtual substrates is the device isolation scheme. Modem integrated circuits rely on transistors that are well isolated from each other. The devices may then be interconnected along arbitrary paths, depending on the desired functionality of the circuit.

Applicants have discovered that standard silicon isolation processes, such as Local Oxidation of Silicon (LOCOS) and Shallow Trench Isolation (STI) utilized in Si CMOS are not satisfactory for processing devices fabricated on strained Si heterostructures such as SiGe virtual substrates. Examples of SiGe virtual substrates include relaxed SiGe on a SiGe graded buffer on a silicon substrate, relaxed SiGe directly on a Si substrate, and relaxed SiGe on insulator (SiO₂) on a silicon substrate.

Applicants have found that when Si heterostructures such as structures including two or more layers of different semiconductor material (e.g., silicon, germanium and silicon germanium), at least one of which is typically strained, are subjected to a LOCOS or STI process, the resulting transistors do not provide optimal performance.

There is a need, therefore, for a method of isolating transistors in a Si heterostructure. In particular, there is a need for a method of isolating transistors on a relaxed SiGe substrate.

### SUMMARY OF THE INVENTION

The invention provides a method for isolating device regions in a heterostructure that includes at least one layer of a strained semiconductor material. In an embodiment, the method includes the steps of forming a trench in the at least one layer of strained semiconductor material using an etch chemistry that is selected to etch different layers of said heterostructure sufficiently similarly that said trench includes walls that are substantially straight, and depositing a dielectric material in the trench. The dielectric material may be SiO₂ and the heterostructure may include stained silicon in certain embodiments.

### BRIEF DESCRIPTION OF THE DRAWINGS

The following description may be further understood with reference to the accompanying drawing in which:

FIGS. 1-8 show illustrative diagrammatic views of the formation of an isolation trench in a silicon heterostructure in accordance with an embodiment of the invention;

FIG. 9 shows an illustrative graphic view of the etch rate of a 10 sccm, 20 mT CF₄ etch through a Si/SiGe heterostructure; and

FIG. 10 shows an illustrative photographic view of a liner oxide grown on a SiGe virtual substrate at 800° C.

The drawings are shown for illustrative purposes and are not to scale.

### DETAILED DESCRIPTION OF THE ILLUSTRATED EMBODIMENTS

Applicants have discovered that attempts to directly transfer standard isolation processes from Si substrates to SiGe virtual substrates are unsuccessful for several reasons. For a process such as LOCOS, the high temperatures typically used to oxidize Si substrates are unsuitable for SiGe virtual substrate-based devices. In that process as well as any high thermal budget process, the thin strained channels of these devices are destroyed by significant interdiffusion during these high temperature oxidation steps (e.g., diffusion of Ge into a strained Si layer from an underlying SiGe layer). Significant interdiffusion can be said to have occurred when the enhanced carrier mobility provided by the thin strained layers is degraded. However, since SiGe alloys oxidize in wet ambient temperatures at much higher rates than Si, lower temperatures could be used in a LOCOS process on SiGe virtual substrates. The oxidation rate of SiGe scales with the Ge content of the alloy, and oxidation may be performed at temperatures as low as 700° C., a regime in which oxidation of Si proceeds at a negligible rate.

The difference in substrate material dictates that many processing changes are made in order to obtain high quality interdevice isolation. Moreover, since these devices may consist of thin, strained layers of Si, Ge, or SiGe, the thermal budget of the process must be limited in order to prevent degradation of the device layers via significant interdiffusion or strain relaxation.

At temperatures below 800° C., the oxidation of SiGe results in the formation of a SiGe-oxide (e.g., SiGeO₂, silicon germanium dioxide), as the Ge atoms in the SiGe matrix are incorporated into the growing oxide, even though pure SiO₂ is its preferred lower energy state. At these lower temperatures, the SiGe virtual substrate may be oxidized for nearly arbitrarily long times without compromising the thermal budget of the strained device layers. However, if the device structure includes thin layers of Si, the oxidation rate will slow immensely as the oxidation of Si at temperatures below 800° C. is very small. Additionally, the SiGe-oxide formed by the low temperature oxidation of SiGe is very susceptible to attack by wet chemical etches in subsequent processing steps. The following table shows a comparison of the wet etch rates of oxides of Si_{0.7}Ge_{0.3} formed at 700° C. and 800° C.

TABLE 1

| SiGe Oxidation | | |
|---|---|---|
| Temperature | Etch Rate in | Etch Rate in |
| (° C.) | 50:1 HF (Å/min) | Hot H₃PO₄ (Å/min) |
| 700 | 1100 | 250 |
| 800 | 60 | ˜0 |

The etch rates of SiGe-oxide increase by orders of magnitude as the oxidation temperature is reduced from 800° C. to 700° C. Hence, during device processing, the SiGe-oxide device isolation is removed at unacceptably high rates, leaving the final devices without isolation and the integrated circuit compromised by shorting paths.

Oxidation of SiGe at temperatures above 800° C. results in the formation of SiO₂, as the Ge atoms in the SiGe matrix are expelled and effectively plowed ahead of the oxidation front. This oxide is functionally identical to the SiO₂ grown on Si substrates, with the associated high resistance to many wet chemical etches used in CMOS processing. However, prolonged exposure to temperatures above 800° C., as described earlier, may result in degradation of the thin, strained Si, Ge, or SiGe device channels that top the SiGe virtual substrate. Moreover, decreasing the oxidation time to minimize the thermal budget of the process results in an unacceptably thin oxide isolation layer. A possible solution to this LOCOS quandary is oxidation at temperatures above 800° C. for abbreviated times to form a chemically resistant SiO₂ layer, followed by oxidation at lower temperatures to increase the isolation layer thickness. In this manner, the poorer quality SiGe-oxide layer lies beneath the more robust SiO₂ layer formed during oxidation above 800° C., and a reasonably thick isolation layer results. However, some removal of the top SiO₂ layer will result during processing, and if the lower SiGe-oxide layer is exposed in the process, large voids in the isolation layer may result where the SiGe oxide is attacked during wet chemical process steps. The potential for this attack on the underlying SiGe-oxide is especially high at the thin, beak-shaped region of the oxide at the edge of the active area. In this region, the robust SiO₂ layer formed at higher temperatures is very thin, and if it is compromised, the underlying poor quality SiGe-oxide is susceptible to chemical attack. Such voids render the device isolation scheme and even the device itself inoperative.

The LOCOS process has been found to be unsuitable for use with SiGe virtual substrates. An alternative device isolation scheme is therefore required. Because the thin strained layers of devices produced on SiGe virtual substrates dictate a reduced processing thermal budget, the isolation scheme must incorporate a deposited isolation material. Since oxide can be deposited at temperatures much lower than those required for oxide growth, a deposited oxide isolation scheme decreases the thermal budget of the device process immensely. Applicants have further discovered that an etch-and-oxide-refill process like a Shallow Trench Isolation (STI) scheme should be used for device processing on SiGe virtual substrates. This is true regardless of device lithography generation. Even at nodes at which LOCOS isolation may be utilized for Si devices (gate lengths>0.25 μm), such an etch-and-refill isolation process is required for device isolation on SiGe substrates. However, the direct application of a standard Si STI process to a structure including a SiGe virtual substrate including a thin strained device layer results in either a non-optimized isolation region, significant interdiffusion in the thin strained device layers that render the structure useless for enhanced performance devices, or both.

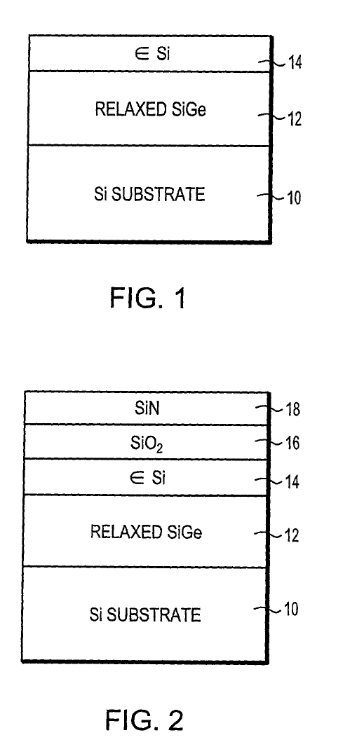

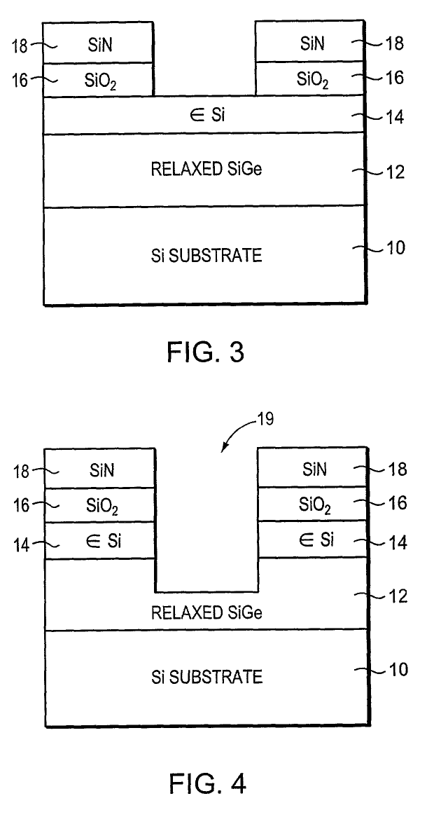

For example, an etch-and-oxide-refill process as adapted for use in the present invention is shown in FIGS. 1-8. As shown in FIG. 1 the Si heterostructure includes a Si substrate 10, a relaxed SiGe layer 12 (e.g., 30% relaxed SiGe) and a strained silicon layer 14 that will serve as the channel layer in transistor devices. The Si heterostructure shown in FIG. 1 may be formed by a variety of methods such as those disclosed in U.S. patent application Ser. No. 09/928,126 filed Aug. 10, 2001, the disclosure of which is hereby incorporated by reference. The active device areas are masked off by a pad oxide/silicon nitride stack including a silicon dioxide (SiO₂) layer 16 and a silicon nitride (SiN) layer 18 as shown in FIG. 2. Next, the oxide/silicon nitride stack is patterned and etched between active device regions as shown in FIG. 3, and the trenches 19 between active device regions are then etched to depths typically less than 1 μm as shown in FIG. 4. Anisotropic, dry etch chemistries are used to maintain vertical and substantially straight trench sidewalls, as shown in FIG. 4. For example, CF₄ may be used to ensure that each of the layers of the strained silicon and the relaxed SiGe are etched along a straight vertical trench line.

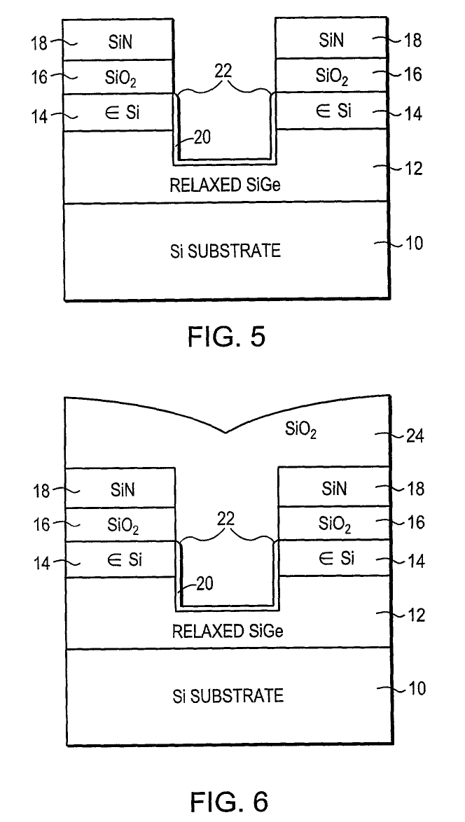

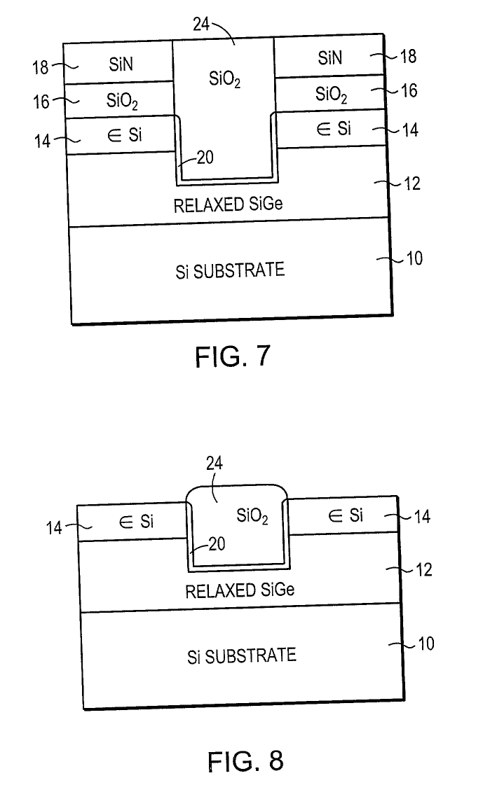

As shown in FIG. 5, a thin (5-30 nm) liner oxide 20 is then grown in the trench in order to remove any etch damage from the trench sidewalls. The liner oxide also acts to smooth the active area corners as shown at 22. Sharp corners result in high fringing electric fields, creating a parasitic transistor with a low threshold voltage at the active area edge and leading to increased subthreshold device leakage. Thus, the liner oxidation process should be carefully engineered in order to optimize device performance. For example, although a liner oxidation may conventionally occur at greater than or equal to 1000° C. for about 30 minutes for silicon, a lower thermal budget (temperature and time) must be employed with strained layer heterostructures. After the liner oxidation, a dielectric layer 24 is deposited over the entire substrate, filling the trenches as shown in FIG. 6. An example of a dielectric layer is silicon dioxide (SiO₂). The dielectric also covers the active device regions as shown and must be selectively removed for device processing to continue. FIG. 7 illustrates the structure following planarization of the substrate, typically via chemical-mechanical polishing (CMP), using the silicon nitride layer 18 over the active area as a stop layer. This process removes the dielectric from the active areas while retaining it in the isolation trenches. The nitride and pad oxide masking layers 16, 18 are then removed, and a highly planar, isolated device substrate results as shown in FIG. 8. This final structure of the isolated device substrate shown in FIG. 8 may include a slightly rounded top surface of the dielectric material 24 following oxide removal as shown in FIG. 8.

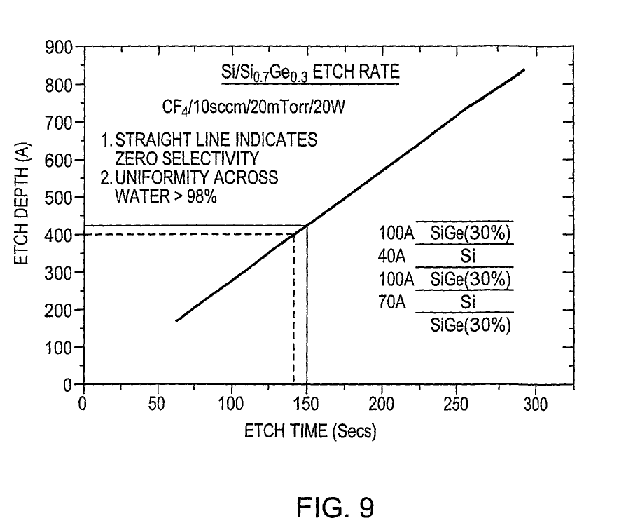

This isolation process must be carefully engineered for use on SiGe virtual substrates. The utilization of a trench process optimized for Si substrates on SiGe substrates will result in poor isolation and/or extremely poor device performance. The different substrate material dictates that the basic process steps be altered to produce high quality device isolation applicable to modern integrated circuit technology while preserving the structure of the thin strained channel layers that provide enhanced transistor performance. First, the chemistry and conditions used for the trench etch must be carefully engineered. Typical Si trench etch processes utilize HBr/Cl₂ chemistries that can exhibit etch selectivity between Si and SiGe materials. The etch properties of SiGe typically differ from those of Si, and depend on the Ge content of the SiGe alloy. Additionally, devices formed atop SiGe virtual substrates incorporate thin layers of Si, Ge, or SiGe with a different Ge content from that of the substrate. In order to achieve vertical trench sidewalls when etching such a layer structure, the etch parameters must be carefully chosen. Any selectivity between Si, Ge, or SiGe in the etch can result in non-vertical trench sidewalls. For example, a thin strained layer of Si or Ge could etch more quickly than the underlying SiGe virtual substrate, resulting in an outward notch in the trench sidewall. Similarly, if the strained layer etches more slowly than the underlying substrate, an overhanging, inward notch will result in the trench. Such trenches are very difficult to fill void-free, and can result in parasitic leakage currents that hinder device performance. Parasitic currents can also result from the irregularities in sidewall shape that result from the notching and these irregularities can form parasitic edge transistors. If such parasitic edge transistors have low enough threshold voltages, the sub-threshold slope of the active device can be degraded. For example, a CF₄-based etch chemistry exhibits no selectivity between Si and SiGe when used at low pressures (˜20 mT) but becomes increasingly selective when the pressure is increased. FIG. 9 shows a graph of the etch rate of a 10 sccm, 20 mT CF₄ etch through a Si/SiGe heterostructure. Regardless of etch time, the etch rate remains constant, indicating no etch selectivity between the Si layers and the Si_{0.7}Ge_{0.3} layers. With no selectivity between Si and SiGe, the materials are etched at the same rates and a straight trench profile results. If the lack of selectivity is not maintained, a non-vertical trench profile will result as the different materials are etched at different rates.

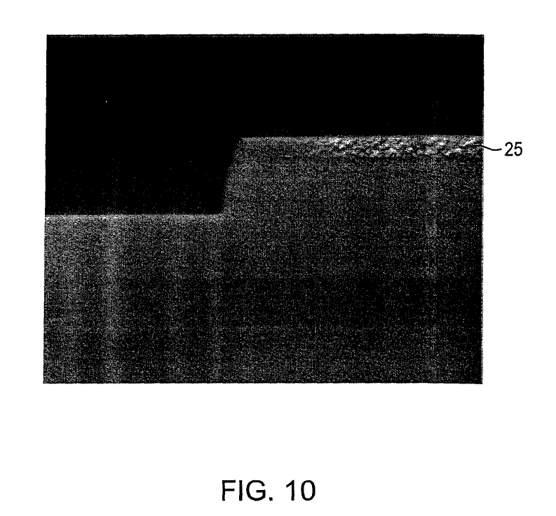

Similarly, the liner oxidation step must be retailored for use with SiGe virtual substrates. This step must be performed at lower temperatures than those normally used with Si substrates in order to preserve the integrity of the thin strained Si, Ge, or SiGe device layers. Typically, liner oxidation of Si substrates consists of a dry oxidation step performed at temperatures of 1000° C. or higher. For adequate corner rounding during the liner oxidation, the properties of the thin device layers must be considered, since they lie at or near the substrate surface. The active area corner must be rounded, but the liner oxide inside the trench must be sufficiently thin to allow adequate filling. Suitable liner oxidation can be performed on SiGe substrates at 800° C. with the correct parameters. FIG. 10 shows a liner oxide 25 grown on a SiGe virtual substrate at 800° C. for 30 minutes in an oxygen ambient. This liner oxidation has resulted in a well-rounded active area corner and has preserved the straight trench profile. Moreover, since the liner oxidation is performed at 800° C., the thin strained device layers on the SiGe substrate are left intact. Similar results could be obtained with higher temperature oxidations, provided that the oxidation time is kept small enough to preserve a low thermal budget, lower than that typically used in a standard Si STI process. The low thermal budget is required in order to prevent significant interdiffusion of the thin strained layers of the heterostructure. Significant interdiffusion can be said to have occurred when the enhanced carrier mobility provided by the thin strained layers is degraded. Thus, the reduced thermal budget liner oxidation is a required element of this isolation scheme on SiGe substrates.

It has been found that the high temperatures and long durations required for oxide growth in conventional LOCOS processes unacceptably degrade thin strained device channels. Moreover, while oxidation of SiGe can be performed at lower temperatures, the resulting oxide is of poor quality. Other typical Si trench isolation processes cannot be directly transferred for processing on SiGe substrates. Because of the importance of nearly vertical trench sidewalls, Si trench etch chemistries have been optimized only for anisotropy. Since mixed Si/SiGe heterostructure devices are used on SiGe substrates, the trench etch must be optimized for both anisotropy and non-selectivity between Si and SiGe in order to obtain vertical sidewalls. Finally, the liner oxidation process, while necessary for the removal of etch damage and for active area corner rounding, must be optimized for use with SiGe substrates. Low thermal budget (e.g., approximately 800° C. for approximately 30-60 minutes, or approximately 850° C. for 15-30 minutes) dry oxidation must be utilized in order to maintain the lower thermal budget dictated by the need to prevent significant interdiffusion of the thin strained device channels. When taken together, these new process steps yield an isolation scheme suitable for use with SiGe substrates.

Those skilled in the art will appreciate that numerous modifications and variations may be made to the above disclosed embodiments without departing from the spirit and scope of the invention.

What is claimed is:

1. A method of isolating device regions in a heterostructure that includes at least one layer of a strained semiconductor material, said method comprising the steps of:
forming a trench in said at least one layer of strained semiconductor material using an etch chemistry that is selected to etch different layers of said heterostructure sufficiently similarly that said trench includes walls that are substantially straight; and
depositing a dielectric material in said trench.

2. The method as claimed in claim 1, where said method further comprises the step of providing a liner oxide at a sufficiently low thermal budget to prevent significant interdiffusion of said at least one layer of strained semiconductor material.

3. The method as claimed in claim 1, wherein said dielectric material includes silicon dioxide.

4. The method as claimed in claim 1, wherein said heterostructure includes at least one layer comprising Si or Ge.

5. The method as claimed in claim 1, wherein said at least one layer of strained semiconductor material comprises Si or Ge.

6. The method as claimed in claim 1, wherein said heterostructure comprises a SiGe layer and said at least one layer of strained semiconductor material comprises Si.

7. The structure formed by the method of claim 1.

8. The structure as claimed in claim 7 wherein said structure includes active area corners that are rounded.

9. A method of isolating device regions in a heterostructure that includes at least one a layer of a strained semiconductor material, said method comprising the steps of:
applying a mask to said heterostructure to provide masked regions and unmasked regions;
etching said unmasked regions to form a trench in at least the at least one layer of strained semiconductor material using an etch chemical that is selected to etch different layers of said heterostructure sufficiently similarly that said trench includes walls that are substantially straight;
providing a liner oxide; and
depositing a dielectric material in said trench;
wherein said method has a thermal budget sufficiently low so as to prevent significant interdiffusion of said at least one layer of strained semiconductor material.

10. The method as claimed in claim 9, wherein said heterostructure includes at least one layer comprising Si or Ge.

11. The method as claimed in claim 9, wherein said at least one layer of strained semiconductor material comprises Si or Ge.

12. The method as claimed in claim 9, wherein said heterostructure comprises a SiGe layer and said at least one layer of strained semiconductor material comprises Si.

13. A structure including at least one layer of a strained semiconductor material and a trench that extends at least through said at least one layer of strained semiconductor material, said trench including a dielectric material and having side walls that are substantially straight.

14. The structure as claimed in claim 13, wherein said structure includes at least one layer comprising Si or Ge.

15. The structure as claimed in claim 13, wherein said trench is formed to a depth of less than about 1 μm.

16. The structure as claimed in claim 13, wherein said structure includes active area corners that are rounded.

17. The structure as claimed in claim 13, wherein said structure includes at least one layer of strained semiconductor material comprising Si or Ge.

18. The structure as claimed in claim 13, wherein said structure includes a layer of SiGe and said at least one layer of strained semiconductor material comprises Si.
